(19) United States
(12) Patent Application Publication
(10) Pub. No.: US 2025/0228107 A1
(43) Pub. Date: Jul. 10, 2025

(54) DISPLAY PANEL, ELECTRONIC DEVICE INCLUDING THE SAME AND MANUFACTURING METHOD OF DISPLAY PANEL

(71) Applicant: Samsung Display Co., Ltd., Yongin-si (KR)

(72) Inventors: JONGWOO KIM, Yongin-si (KR); SOYOUNG OH, Yongin-si (KR); HYUNSUP YOON, Yongin-si (KR); WOOSUK JUNG, Yongin-si (KR); YONGCHAN JU, Yongin-si (KR); JAEHEUNG HA, Yongin-si (KR)

(21) Appl. No.: 18/954,127

(22) Filed: Nov. 20, 2024

(30) Foreign Application Priority Data
Jan. 5, 2024 (KR) 10-2024-0002037

(51) Int. Cl. H10K 59/80; H10K 59/12; H10K 59/122; H10K 59/40

(52) U.S. Cl. CPC H10K 59/873; H10K 59/1201; H10K 59/122; H10K 59/40

(57) ABSTRACT

A display panel according to one or more embodiments of the present disclosure includes a display element layer including a pixel-defining layer defining a pixel opening, and a light-emitting element, and an encapsulation layer above the display element layer, and including a first inorganic encapsulation layer having a refractive index of about 1.90 or more to about 2.10 or less above the display element layer, a second inorganic encapsulation layer having a refractive index of about 1.90 or more to about 2.10 or less above the first inorganic encapsulation layer, a third inorganic encapsulation layer having a refractive index of about 1.90 or more to about 2.10 or less above the second inorganic encapsulation layer, and an organic encapsulation layer having a dielectric constant of about 1.0 or more to about 2.5 or less above the third inorganic encapsulation layer.

### CROSS-REFERENCE TO RELATED APPLICATION

The present application claims priority to, and the benefit of, Korean Patent Application No. 10-2024-0002037, filed on Jan. 5, 2024, in the Korean Intellectual Property Office, the entire disclosure of which is incorporated herein by reference.

### BACKGROUND

### 1. Field

The present disclosure herein relates to a display panel, an electronic device having a reduced thickness, and in which an input sensor located at an upper portion of a display panel has an improved sensing performance, and a manufacturing method of the display panel.

### 2. Description of the Related Art

Various types of display devices are used to provide image information. A self-light-emitting display device made of an organic light-emitting material or a quantum dot light-emitting material is being developed. Because the self-light-emitting display device includes a light-emitting element, and because the light-emitting element is vulnerable to an external environment, such as oxygen and moisture, various techniques for sealing the light-emitting element are suitable. Among the techniques, a technique for arranging an encapsulation layer on the light-emitting element to block a penetration path of air and moisture is being developed. The encapsulation layer may include an inorganic layer containing an inorganic material and an organic layer containing an organic material.

### SUMMARY

The present disclosure provides a display panel, which has a reduced thickness and improved flexible characteristics, and which includes an input sensor located at an upper portion of the display panel and having an improved sensing performance, and an electronic device including the same.

The present disclosure also provides a method for manufacturing a display panel, which manufactures a display panel having a reduced thickness through a simplified process.

One or more embodiments of the present disclosure provides a display panel including a display element layer including a pixel-defining layer defining a pixel opening, and a light-emitting element, and an encapsulation layer above the display element layer, and including a first inorganic encapsulation layer having a refractive index of about 1.90 or more to about 2.10 or less above the display element layer, a second inorganic encapsulation layer having a refractive index of about 1.90 or more to about 2.10 or less above the first inorganic encapsulation layer, a third inorganic encapsulation layer having a refractive index of about 1.90 or more to about 2.10 or less above the second inorganic encapsulation layer, and an organic encapsulation layer having a dielectric constant of about 1.0 or more to about 2.5 or less above the third inorganic encapsulation layer.

The organic encapsulation layer may be directly on the third inorganic encapsulation layer.

The second inorganic encapsulation layer may be directly on the first inorganic encapsulation layer, wherein the third inorganic encapsulation layer is directly on the second inorganic encapsulation layer.

The first inorganic encapsulation layer, the second inorganic encapsulation layer, and the third inorganic encapsulation layer may include a same material.

The first inorganic encapsulation layer, the second inorganic encapsulation layer, and the third inorganic encapsulation layer may include at least one of a silicon nitride, a silicon oxide, or a silicon oxynitride.

The second inorganic encapsulation layer may have a thickness that is greater than a thickness of the first inorganic encapsulation layer and is greater than a thickness of the third inorganic encapsulation layer.

The first inorganic encapsulation layer and the third inorganic encapsulation layer may have a thickness of about 1 Å or more to about 10 Å or less, wherein the second inorganic encapsulation layer has a thickness of about 1500 Å or more to about 2000 Å or less.

The organic encapsulation layer may have a thickness of about 3 μm or more to about 8 μm or less.

A top surface of the second inorganic encapsulation layer may include a planarized surface.

The second inorganic encapsulation layer may have a water vapor transmission rate of about 1×10−4 g/m²·day or more to about 9×10−4 g/m²·day or less.

The encapsulation layer may cover the light-emitting element.

The light-emitting element may include a first electrode exposed through the pixel opening, a second electrode above the first electrode, and a light-emitting layer between the first electrode and the second electrode.

The light-emitting element may further include a hole control layer between the first electrode and the light-emitting layer, and an electron control layer between the light-emitting layer and the second electrode.

A top surface of the organic encapsulation layer may define an uppermost surface of the encapsulation layer.

In one or more embodiments of the present disclosure, an electronic device includes an input sensor including conductive patterns, a display panel below the input sensor, and including light-emitting areas, a display element layer including a pixel-defining layer defining a pixel opening, and a light-emitting element, and an encapsulation layer above the display element layer, and including a first inorganic encapsulation layer having a refractive index of about 1.90 or more to about 2.10 or less above the display element layer, a second inorganic encapsulation layer having a refractive index of about 1.90 or more to about 2.10 or less above the first inorganic encapsulation layer, a third inorganic encapsulation layer having a refractive index of about 1.90 or more to about 2.10 or less above the second inorganic encapsulation layer, and an organic encapsulation layer having a dielectric constant of about 1.0 or more to about 2.5 or less above the third inorganic encapsulation layer.

The input sensor may be directly on the organic encapsulation layer.

The input sensor may include a first sensor insulation layer directly on the organic encapsulation layer, a first sensor conductive layer above the first sensor insulation layer, a second sensor insulation layer above the first sensor insulation layer to cover the first sensor conductive layer, and a second sensor conductive layer above the second sensor insulation layer.

The electronic device further comprises a housing that accommodates the display panel and the input sensor.

In one or more embodiments of the present disclosure, a method for manufacturing a display panel includes forming a display element layer including a pixel-defining layer and a light-emitting element, and forming an encapsulation layer on the display element layer to cover the light-emitting element by forming a first inorganic encapsulation layer having a refractive index of about 1.90 or more to about 2.10 or less on the display element layer, forming a second inorganic encapsulation layer having a refractive index of about 1.90 or more to about 2.10 or less on the first inorganic encapsulation layer, forming a third inorganic encapsulation layer having a refractive index of about 1.90 or more to about 2.10 or less on the second inorganic encapsulation layer, and forming an organic encapsulation layer having a dielectric constant of about 1.0 or more to about 2.5 or less on the third inorganic encapsulation layer.

The forming of the first inorganic encapsulation layer may include a plasma-enhanced atomic layer deposition (PEALD) or physical vapor deposition (PVD) process, wherein the forming of the second inorganic encapsulation layer includes a plasma-enhanced chemical vapor deposition (PECVD) process, and wherein the forming of the third inorganic encapsulation layer includes a PEALD or PVD process.

The first inorganic encapsulation layer, the second inorganic encapsulation layer, and the third inorganic encapsulation layer may be formed through a same silicon precursor.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIGS. 1A, 1B, and 1C are perspective views illustrating a display device according to one or more embodiments of the present disclosure;

FIG. 2 is an exploded perspective view illustrating the display device according to one or more embodiments of the present disclosure;

FIG. 3 is a perspective view illustrating a display device according to one or more other embodiments of the present disclosure;

FIG. 4 is a cross-sectional view illustrating the display device according to one or more embodiments of the present disclosure;

FIG. 5 is a cross-sectional view illustrating a display module according to one or more embodiments of the present disclosure;

FIG. 6 is a plan view illustrating a display panel according to one or more embodiments of the present disclosure;

FIG. 7 is an enlarged cross-sectional view illustrating the display module according to one or more embodiments of the present disclosure;

FIG. 8 is an enlarged cross-sectional view illustrating the display module according to one or more embodiments of the present disclosure;

FIG. 9 is a cross-sectional view illustrating a partial configuration of the display module according to one or more embodiments of the present disclosure;

FIG. 10A is a flowchart representing a method for manufacturing a display panel according to one or more embodiments of the present disclosure;

FIG. 10B is a flowchart representing some processes of the method of manufacturing the display panel according to one or more embodiments of the present disclosure; and

FIGS. 11A, 11B, 11C, 11D, and 11E are cross-sectional views respectively illustrating the some processes of the method of manufacturing the display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

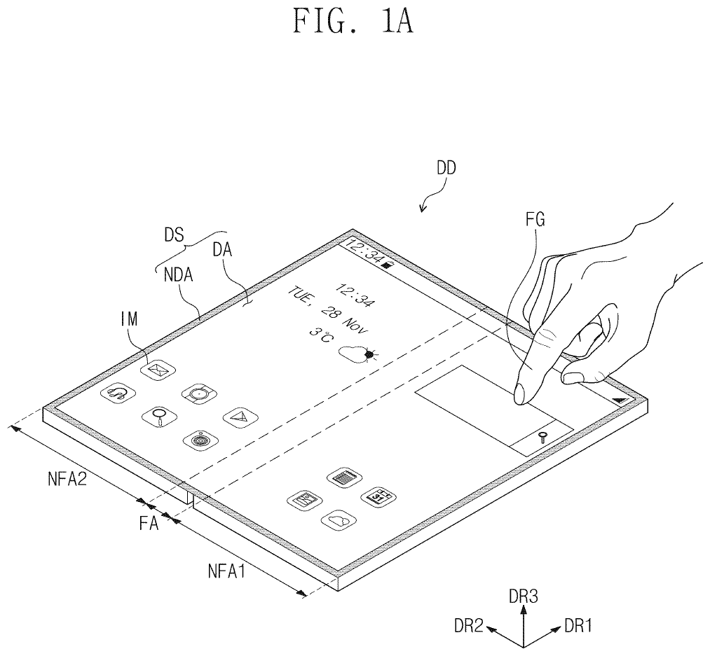

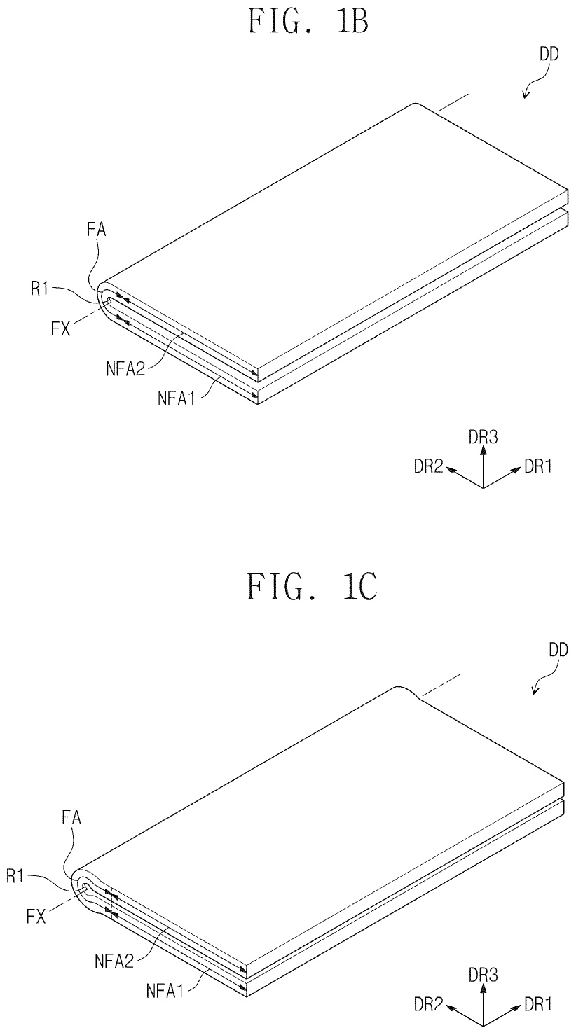

FIGS. 1A, 1B, and 1C are perspective views of a display device DD according to one or more embodiments of the present disclosure. FIG. 1A illustrates an unfolded state, and FIGS. 1B and 1C illustrate a folded state.

Referring to FIGS. 1A and 1B, the display device DD according to one or more embodiments of the present disclosure may include a display surface DS defined by a first direction DR1, and by a second direction DR2 crossing the first direction DR1. The display device DD may provide an image IM to a user through the display surface DS.

The display surface DS may include a display area DA, and a non-display area NDA around the display area DA. The display area DA may display the image IM, and the non-display area NDA may not display the image IM. The non-display area NDA may surround the display area DA (e.g., in plan view). However, the present disclosure is not limited thereto. For example, each of the display area DA and the non-display area NDA may be deformed in shape.

Hereinafter, a direction that crosses a plane defined by the first and second directions DR1 and DR2 in a substantially perpendicular manner is defined as a third direction DR3. The third direction DR3 is a reference that differentiates a front surface and a rear surface of each of members. In this specification, an expression “viewed on a plane” may be defined as a state when viewed in the third direction DR3. Hereinafter, the first to third directions DR1, DR2, and DR3 are indicated by first to third directional axes and designated by the same reference numerals, respectively.

The display device DD may include a folding area FA and a plurality of non-folding areas NFA1 and NFA2. The non-folding areas NFA1 and NFA2 may include a first non-folding area NFA1 and a second non-folding area NFA2. In the second direction DR2, the folding area FA may be located between the first non-folding area NFA1 and the second non-folding area NFA2. Although the foldable display device DD is illustrated as an example, the present disclosure is not limited thereto. The display device DD may be a bar, rollable, or sliceable-type display device.

The display device DD may detect an input caused by a body FG of a user.

A finger is illustrated as an example of the body FG of the user.

As illustrated in FIG. 1B, the folding area FA may be folded around a folding axis FX parallel to the first direction DR1. The folding area FA has a curvature (e.g., predetermined curvature) and a radius R1 of curvature. The display device DD may be inner-folded so that the display surface DS is not exposed to the outside, and the first non-folding area NFA1 and the second non-folding area NFA2 face each other.

In one or more embodiments of the present disclosure, the display device DD may be outer-folded so that the display surface DS is exposed to the outside. In one or more embodiments of the present disclosure, the display device DD may perform an inner-folding or outer-folding operation from an unfolding operation in a repeated manner. However, the present disclosure is not limited thereto. In one or more embodiments of the present disclosure, the display device DD may select one of the unfolding operation, the inner-folding operation, and the outer-folding operation.

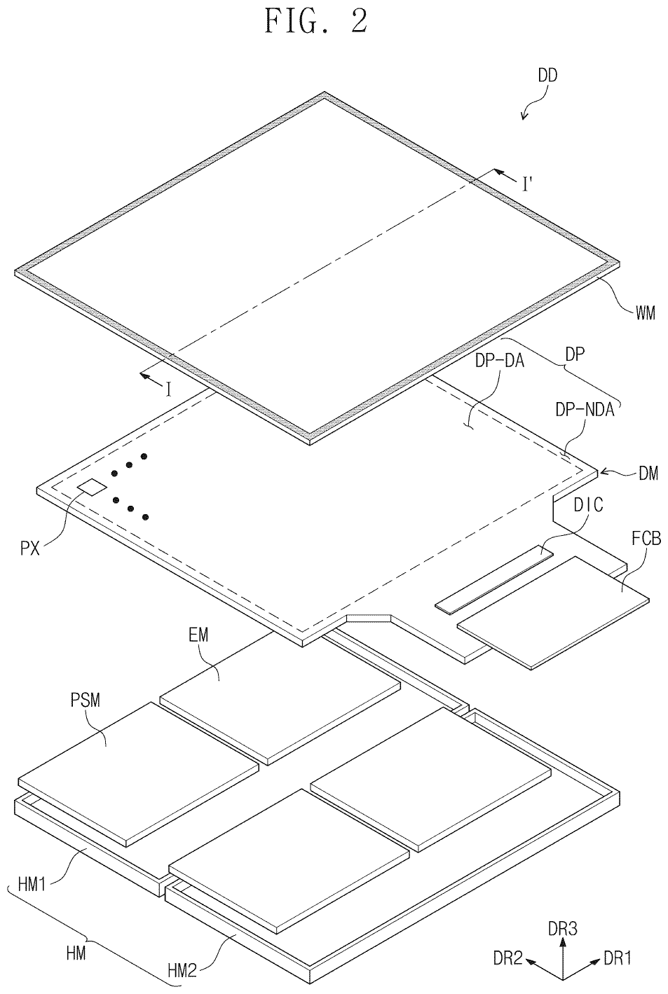

Although a distance between the first non-folding area NFA1 and the second non-folding area NFA2 may be substantially equal to two times of the radius R1 of curvature as illustrated in FIG. 1B, the distance between the first non-folding area NFA1 and the second non-folding area NFA2 may be less than two times of the radius R1 of curvature as illustrated in FIG. 1C. FIGS. 1B and 1C are illustrated based on the display surface DS, and a housing HM (refer to FIG. 2) that provides an outer shape of the display device DD may contact an end area of the first non-folding area NFA1 and the second non-folding area NFA2.

The display device DD that is applicable to a mobile terminal is illustrated as an example. As electronic modules mounted on a main board, a camera module, and/or a power supply module are located on a bracket or case in conjunction with the display device DD, the mobile phone may be formed. However, the present disclosure is not limited thereto. For example, the display device DD according to one or more embodiments of the present disclosure may be applied to large-sized electronic devices, such as televisions and monitors and small and medium-sized electronic devices, such as tablet computers, navigation units for vehicles, game consoles, and smart watches.

FIG. 2 is an exploded perspective view of the display device DD according to one or more embodiments of the present disclosure.

As illustrated in FIG. 2, the display device DD may include an electronic module EM, a power supply module PSM, and a housing HM. In one or more embodiments, the display device DD may further include a mechanism structure for controlling a folding operation of the display device DD. In one or more embodiments, an adhesive layer may couple components to each other.

The display device DD generates an image, and detects an external input.

The display device DD includes a window WM and a display module DM. The window WM provides a front surface of the display device DD. The display device DD may further include an additional component located between the window WM and the display module DM, or an additional component located below the display module DM.

The display module DM may include at least a display panel DP. Although only the display panel DP in a laminated structure of the display module DM is illustrated in FIG. 2, the display module DM may substantially further include a plurality of components located on the display panel DP. A detailed description on the laminated structure of the display module DM will be described later.

However, the present disclosure is not limited to the display panel DP. For example, the display panel DP may be a light-emitting display panel, such as an organic light-emitting display panel or an inorganic light-emitting display panel.

The display panel DP includes a display area DP-DA and a non-display area DP-NDA, which correspond to the display area DA (refer to FIG. 1A) and the non-display area NDA (refer to FIG. 1A), respectively. A pixel PX is located on the display area DP-DA. A signal line that provides a voltage to the pixel PX is located on the non-display area DP-NDA instead of the pixel PX. In this specification, an expression “an area or portion corresponds to another area or portion” represents that the area or portion overlaps another area or portion and is not limited to the same surface area.

As illustrated in FIG. 2, a driving chip DIC may be located on the non-display area DP-NDA of the display panel DP. A flexible circuit board FCB may be coupled to the non-display area DP-NDA of the display panel DP. The flexible circuit board FCB may be connected to a main circuit board. The main circuit board may be one electronic component of the electronic module EM. Additionally, the electronic module EM may further include a control module (e.g., an application processor), a wireless communication module, or an image input module. Unlike FIG. 2, a portion of the flexible circuit board FCB may be located below the display panel DP. In the display device DD according to one or more embodiments, as a portion of the display module DM or the flexible circuit board FCB is bent, a portion of the flexible circuit board FCB may be located below the display panel DP.

The driving chip DIC may include driving elements for driving the pixel PX, such as a data driving circuit. Although a structure in which the driving chip DIC is mounted onto the display panel DP is illustrated in FIG. 2, the present disclosure is not limited thereto. For example, the driving chip DIC may be mounted onto the flexible circuit board FCB.

Referring to FIG. 2, the electronic module EM may be located on each of a first housing HM1 and a second housing HM2, and the power supply module PSM may be located on each of a first housing HM1 and a second housing HM2. In one or more embodiments, the electronic module EM located on the first housing HM1 and the electronic module EM located on the second housing HM2 may be electrically connected through a flexible circuit board. The housing HM is coupled with the display device DD, such as the window WM, to accommodate the above-described other modules. Although the housing HM includes the first and second housings HM1 and HM2 that are separated from each other, the present disclosure is not limited thereto. In one or more embodiments, the display device DD may further include a hinge structure for connecting the first and second housings HM1 and HM2.

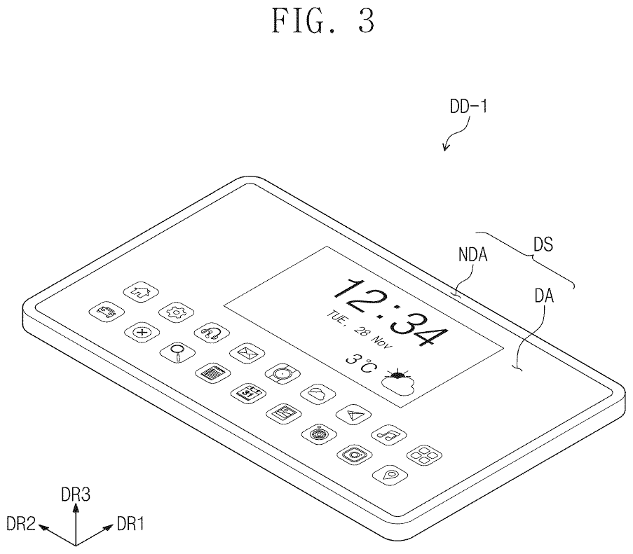

FIG. 3 is a perspective view illustrating a display device DD-1 according to one or more other embodiments of the present disclosure. As illustrated in FIG. 3, the display device DD-1 may display an image through a display surface DS. The display surface DS may have a rectangular shape having long sides extending in the second direction DR2, and short sides extending in the first direction DR1 on a plane. However, the present disclosure is not limited thereto. For example, the display device DD-1 may have various shapes, such as a circular shape or a polygonal shape.

Although the display device DD-1 having a flat display surface is illustrated in one or more embodiments of the present disclosure, the present disclosure is not limited thereto. The display device DD-1 may include a curved display surface or a three-dimensional display surface. The three-dimensional display surface may include a plurality of display areas indicating different directions from each other, and may also include, for example, a bent display surface. The display device DD-1 may be a flexible display device. The display device DD-1 may be a foldable display device capable of being folded.

The display device DD-1 that is applicable to a tablet computer is illustrated as an example. As electronic modules mounted on a main board, a camera module, and a power supply module are located on a bracket or a case in conjunction with the display device DD-1, and the tablet computer may be formed. The display device DD-1 according to one or more embodiments of the present disclosure may be used for large-sized electronic devices, such as televisions and monitors, and small- and medium-sized electronic devices, such as mobile phones, navigation units for vehicles, game consoles, and smart watches.

As illustrated in FIG. 3, the display surface DS includes a display area DA on which an image is displayed and a non-display area NDA located adjacent to the display area DA. The non-display area NDA is an area on which an image is not displayed. FIG. 3 illustrates icon images as an example of the image.

As illustrated in FIG. 3, the display area DA may have a substantially rectangular shape. The term “substantially rectangular shape” includes not only a rectangular shape in terms of mathematics, but also a rectangular shape in which a boundary of a curve is defined at a vertex area (or a corner area) instead of a vertex.

The non-display area NDA may surround the display area DA. However, the present disclosure is not limited thereto. For example, the non-display area NDA may be deformed in shape. For example, the non-display area NDA may be located at one side of the display area DA.

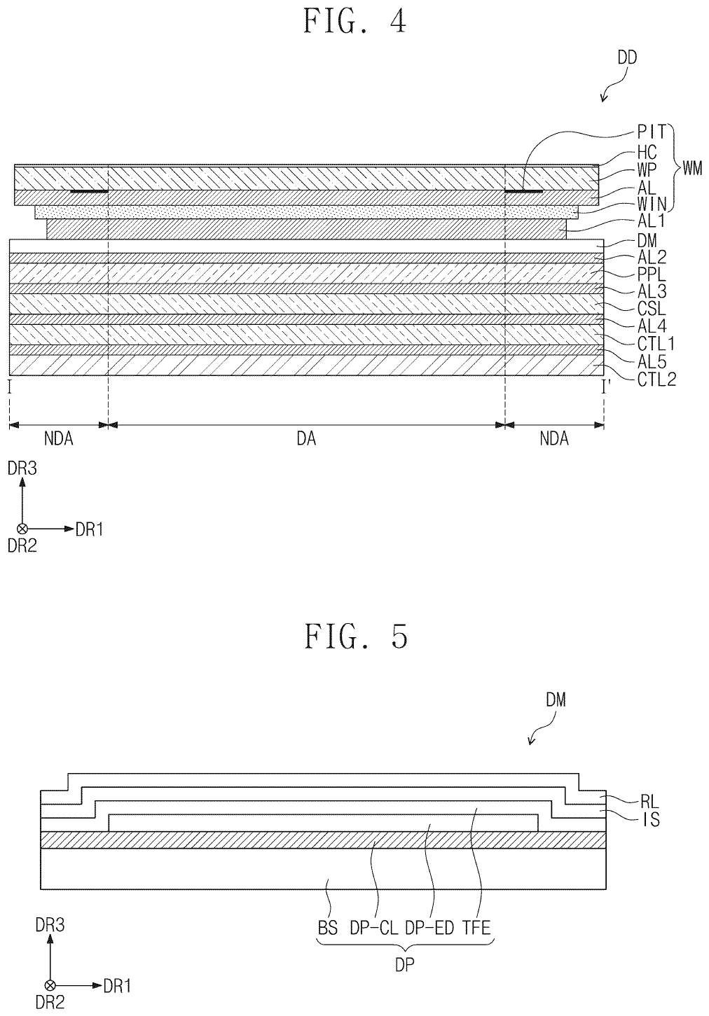

FIG. 4 is a cross-sectional view illustrating the display device according to one or more embodiments of the present disclosure. FIG. 4 is a cross-sectional view taken along the line I-I′ of FIG. 2.

Referring to FIG. 4, the display device DD may include a window WM, a display module DM, a panel protection layer PPL, a cushion layer CSL, a first lower layer CTL1, a second lower layer CTL2, and first to fifth adhesive layers AL1 to AL5. Each of the first to fifth adhesive layers AL1 to AL5 couples two adjacent components among components. Each of the first to fourth adhesive layers AL1 to AL5 may include a pressure sensitive adhesive (PSA) or an optically clear adhesive (OCA). However, the present disclosure is not limited to the kind of the adhesive layer.

The window WM provides an outer surface of the display device DD. The window WM may include a base layer WIN, a window protection layer WP, a hard coating layer HC, and a printed layer PIT (or a black matrix layer). The base layer WIN may have an optically transparent property. The window WM may include glass or a synthetic resin film. The window protection layer WP is attached onto the base layer WIN through the adhesive layer AL. The window protection layer WP may include a flexible plastic material, such as polyimide or polyethylene terephthalate. The hard coating layer HC may be located on a top surface of the window protection layer WP (as used herein, “located on” may mean “above” or “below”).

The printed layer PIT may be located on/below a bottom surface of the window protection layer WP. The printed layer PIT may be a black matrix layer. Although the printed layer PIT may have a black color, the present disclosure is not limited to the color of the printed layer PIT. The printed layer PIT may be located on an edge of the window protection layer WP. The printed layer PIT may overlap the non-display area NDA. However, the present disclosure is not limited to the above-described laminated structure of the window WM.

The panel protection layer PPL may be located below the display module DM. The panel protection layer PPL may protect a lower portion of the display module DM. The panel protection layer PPL may include a flexible plastic material. For example, the panel protection layer PPL may include polyethylene terephthalate (PET). In one or more embodiments of the present disclosure, the panel protection layer PPL may be omitted.

The cushion layer CSL is located below the panel protection layer PPL. The cushion layer CSL absorbs an external impact. The cushion layer CSL may include foamed plastic. In one or more embodiments of the present disclosure, the cushion layer CSL may be omitted.

The first lower layer CTL1 may be located below the cushion layer CSL. The first lower layer CTL1 may be located below the cushion layer CSL to protect components located thereabove from an external impact. The first lower layer CTL1 may include a material having a stiffness (e.g., predetermined stiffness). The first lower layer CTL1 may include, for example, a metal plate. Alternatively, the first lower layer CTL1 may include a material having high permeability. The first lower layer CTL1 may include a ferromagnetic material. For example, the first lower layer CTL1 may include a magnetic metal powder layer. The magnetic metal powder layer may include a base resin, and magnetic metal powder mixed in the base resin. In one or more embodiments of the present disclosure, the first lower layer CTL1 may be omitted.

The second lower layer CTL2 may be located below the first lower layer CTL1. The second lower layer CTL2 may block or reduce an electromagnetic wave generated by the electronic module EM of FIG. 2 so that the electromagnetic wave does not interfere with the display module DM. The second lower layer CTL2 may include a diamagnetic material. Also, the second lower layer CTL2 may dissipate heat generated from the display module DM, such as from the driving chip DIC (refer to FIG. 2).

The second lower layer CTL2 may include a metal layer, such as copper, aluminum, gold, or titanium. The second lower layer CTL2 may include a metal oxide layer, such as ITO or IZO. The second bottom layer CTL2 may include a carbon nanotube, a carbon nanotube coated with a conductive polymer, or graphite.

FIG. 5 is a cross-sectional view of the display module DM according to one or more embodiments of the present disclosure. Referring to FIG. 5, the display module DM may include a display panel DP, an input sensor IS, and an anti-reflector RL.

The display panel DP may include a base layer BS, a circuit element layer DP-CL, a display element layer DP-ED, and an encapsulation layer TFE. The base layer BS may provide a base surface on which the circuit element layer DP-CL is located.

The base layer 110 may be a rigid board or a flexible board that is bendable, foldable, or rollable.

The base layer BS may have a single-layered structure or a multi-layered structure. The base layer BS according to one or more embodiments may include a single resin layer or a plurality of resin layers. The base layer BS may include a plurality of resin layers, and a single inorganic layer or a plurality of inorganic layers respectively located between the plurality of resin layers.

The circuit element layer DP-CL may be located on the base layer BS. The circuit element layer DP-CL may include an insulation layer, a semiconductor pattern, a conductive pattern, and a signal line. The circuit element layer DP-CL includes a driving circuit of the pixel PX described with reference to FIG. 2. The display element layer DP-ED may be located on the circuit element layer DP-CL. The display element layer DP-ED includes a light-emitting element of the pixel PX described with reference to FIG. 2.

The encapsulation layer TFE is located on the display element layer DP-ED. The encapsulation layer TFE may protect the display element layer DP-ED from moisture, oxygen, and foreign substances, such as dust particles. The encapsulation layer TFE may include at least one inorganic layer and at least one organic layer. The encapsulation layer TFE includes a laminated structure of the inorganic layer and the organic layer. A configuration of the encapsulation layer TFE will be described later in more detail.

The input sensor IS may be located on the display panel DP. The input sensor IS may detect an input of a stylus pen and an input of the body FG of the user. The input sensor IS may be provided continually on the display panel DP. In this case, the input sensor IS may be located directly on the display panel DP. The input sensor IS may be located directly on the encapsulation layer TFE. In this specification, an expression “component A is located directly on component B” may mean that an adhesive layer is not located between the component A and the component B.

The anti-reflector RL may be located on the input sensor IS. The anti-reflector RL may reduce a reflectance of external light. The anti-reflector RL may be located directly on the input sensor IS through a continuous process.

The anti-reflector RL may include a color filter. The color filter has a color corresponding to that of source light. For example, a red color filter is located on a light-emitting element that emits red light. The anti-reflector RL may further include a light-blocking pattern located between the color filters.

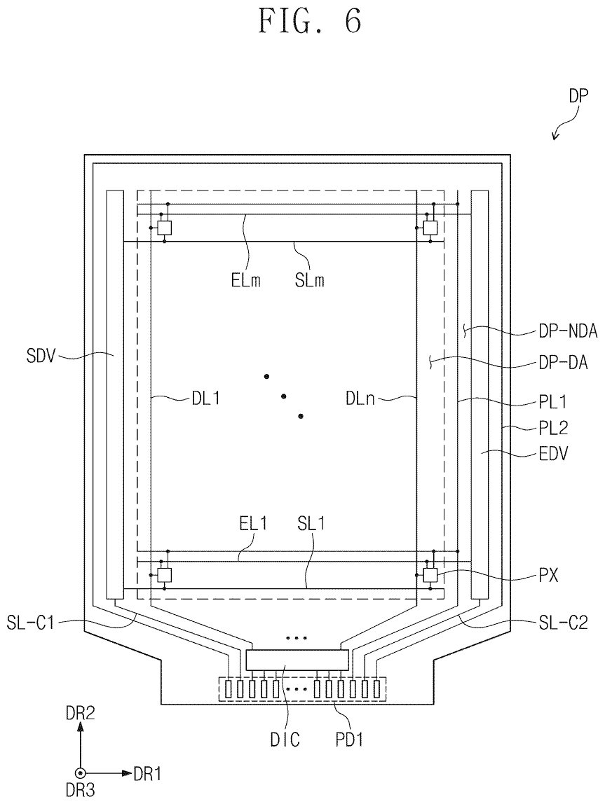

FIG. 6 is a plan view illustrating the display panel DP according to one or more embodiments of the present disclosure.

Referring to FIG. 6, the display panel DP may include a plurality of pixels PX, a scan driver SDV, an emission driver EDV, a plurality of signal lines, and a plurality of first pads PD1. The driving chip DIC mounted to the non-display area DP-NDA may include a data driver. In one or more embodiments of the present disclosure, the data driver may be also integrated with the display panel DP as with the scan driver SDV and the emission driver EDV.

The plurality of signal lines may include a plurality of scan lines SL1 to SLm, a plurality of data lines DL1 to DLn, a plurality of emission lines EL1 to ELm, first and second control lines SL-C1 and SL-C2, and first and second power lines PL1 and PL2. Here, each of reference symbols m and n is a natural number equal to or greater than 2.

The scan lines SL1 to SLm may each extend in the second direction DR2, and may be connected to the pixels PX and the scan driver SDV. The data lines DL1 to DLn may each extend in the first direction DR1, and may be connected to the pixels PX and the driving chip DIC. The emission lines EL1 to ELm may each extend in the second direction DR2, and may be connected to the pixels PX and the emission driver EDV.

The first power line PL1 receives a first power voltage, and the second power line PL2 receives a second power voltage that is less/lower in level than the first power voltage. In one or more embodiments, a second electrode (e.g., a cathode) of the light-emitting element is connected to the second power line PL2.

A first control line SL-C1 may be connected to the scan driver SDV, and may extend toward a lower end of the display panel DP. The second control line SL-C2 may be connected to the emission driver EDV, and may extend toward the lower end of the display panel DP. The first pads PD1 may be located on the non-display area DP-NDA adjacent to the lower end of the display panel DP, and may be located closer to the lower end of the display panel DP than the driving chip DIC. The first pads PD1 may be connected to the driving chip DIC and some of the signal lines.

The scan driver SDV may generate a plurality of scan signals, and the scan signals may be applied to the pixels PX through the scan lines SL1 to SLm. The driving chip DIC may generate a plurality of data voltages, and the data voltages may be applied to the pixels PX through the data lines DL1 to DLn. The emission driver EDV may generate a plurality of emission signals, and the emission signals may be applied to the pixels PX through the emission lines EL1 to ELm.

The pixels PX may receive the data voltages in response to the scan signals. The pixels PX may display an image by emitting light having luminance corresponding to the data voltages in response to the emission signals.

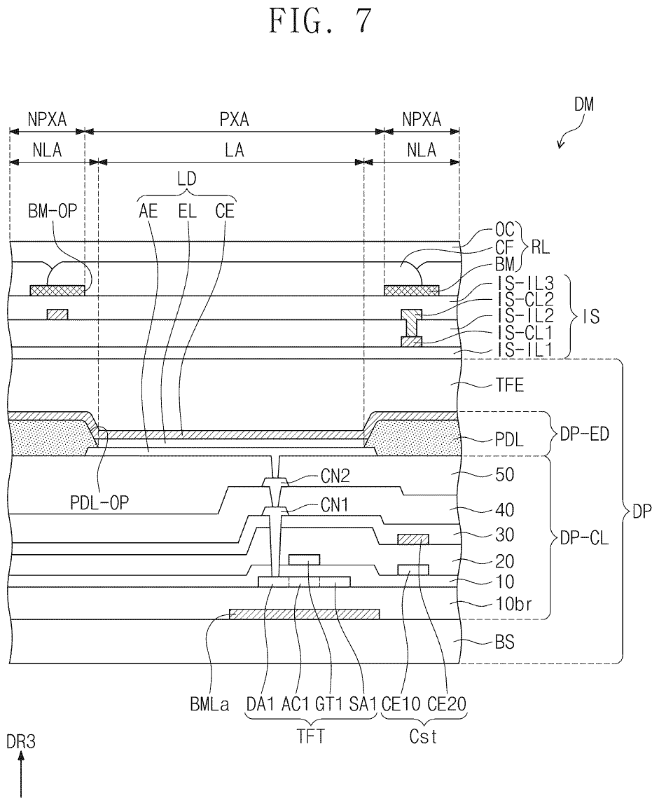

FIG. 7 is a cross-sectional view illustrating the display module DM according to one or more embodiments of the present disclosure.

FIG. 7 illustrates a cross-section corresponding to one light-emitting area LA and a surrounding non-light-emitting area NLA. FIG. 7 illustrates a cross-section of a light-emitting element LD contained in one pixel PX and a transistor TFT connected thereto. The transistor TFT may be one of a plurality of transistors included in the driving circuit of the pixel PX. Although the transistor TFT is described as a silicon transistor, the transistor TFT may be an oxide transistor in one or more other embodiments.

In FIG. 7, the base layer BS is illustrated as a single layer. The base layer BS may include synthetic resin, such as polyimide. In one or more embodiments, the base layer BS may be provided by applying a synthetic resin layer onto a work substrate (or carrier substrate), and the work substrate may be removed when the display module DM is completed in a subsequent process.

The base layer BS may have a single-layered or multi-layered structure. For example, the base layer BS may include a first synthetic resin layer, an intermediate layer having a single-layered or multi-layered structure, and a second synthetic resin layer, which are laminated in order. The intermediate layer may be referred to as a base barrier layer. The intermediate layer may include a silicon oxide (SiOx) layer, and an amorphous silicon (a-Si) layer located on the silicon oxide layer. However, the present disclosure is not limited thereto. For example, the intermediate layer may include at least one of a silicon oxide layer, a silicon nitride layer, a silicon oxynitride layer, or an amorphous silicon layer.

Each of the first and second synthetic resin layers may include a polyimide-based resin. Also, each of the first and second synthetic resin layers may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a term “a”-based resin represents a feature of including a functional group of “a”.

A buffer layer 10br may be located on the base layer BS. The buffer layer 10br may reduce or prevent metal atoms or impurities being diffused from the base layer 110 to a semiconductor pattern located thereabove. The semiconductor pattern includes an active region AC1 of the transistor TFT.

A shielding pattern BMLa may be located below the transistor TFT. The shielding pattern BMLa may block external light from arriving at the transistor TFT. The shielding pattern BMLa may be located between the base layer BS and the buffer layer 10br. In one or more embodiments of the present disclosure, an inorganic barrier layer may be further located between the shielding pattern BMLa and the buffer layer 10br. The shielding pattern BMLa may be connected to an electrode or a line, and may receive a constant voltage or a signal therefrom.

A semiconductor pattern may be located on the buffer layer 10br. The semiconductor pattern may include a silicon semiconductor. For example, the silicon semiconductor may include amorphous silicon and/or polycrystalline silicon. For example, the semiconductor pattern may include low temperature polysilicon.

The semiconductor pattern may include a first area having high conductivity, and a second area having low conductivity. The first area may be doped with an n-type dopant or a p-type dopant. A p-type transistor may include a doped area that is doped with the p-type dopant, and an n-type transistor may include a doped area that is doped with the n-type dopant. The second area may be a non-doped area, or may be a doped area having a concentration less than that of the first area.

The first area may have conductivity that is greater than that of the second area, and may substantially serve as an electrode or a signal line. The second area may substantially correspond to an active region (or a channel) of the transistor. In other words, one portion of the semiconductor pattern may be the active region of the transistor, another portion may be a source or a drain of the transistor, and another portion may be a connection electrode or a connection signal line.

A source region SA1 (or source), an active region AC1 (or channel), and a drain region DA1 (or drain) of the transistor TFT may be provided from the semiconductor pattern. The source region SA1 and the drain region DA1 may extend in opposite directions from the active region AC1 on the cross-section.

A first insulation layer 10 may be located on the buffer layer 10br. The first insulation layer 10 may overlap the plurality of pixels PX (refer to FIG. 1) in common, and may cover the semiconductor pattern. The first insulation layer 10 may be an inorganic layer and/or an organic layer, and may have a single-layered or multi-layered structure. The inorganic layer may include at least one of an aluminum oxide, a titanium oxide, a silicon oxide, a silicon nitride, a silicon oxynitride, a zirconium oxide, or a hafnium oxide. The first insulation layer 10 may be a single-layered silicon oxide layer. In addition to the first insulation layer 10, an insulation layer of the circuit element layer DP-CL, which will be described later, may be an inorganic layer and/or an organic layer, and may have a single-layered or multi-layered structure. Although the inorganic layer may include at least one of the above-described materials, the present disclosure is not limited thereto.

A gate GT1 of the transistor TFT is located on the first insulation layer 10. The gate GT1 may be a portion of a metal pattern. The gate GT1 overlaps the active region AC1. The gate GT1 may serve as a mask in a process of doping the semiconductor pattern. Although the gate GT1 may include titanium (Ti), silver (Ag), an alloy containing silver, molybdenum (Mo), an alloy containing molybdenum, aluminum (AI), an alloy containing aluminum, aluminum nitride (AlN), tungsten (W), a tungsten nitride (WN), copper (Cu), an indium tin oxide (ITO), and/or an indium zinc oxide (IZO), the present disclosure is not limited thereto.

A second insulation layer 20 may be located on the first insulation layer 10 to cover the gate GT1. A third insulation layer 30 may be located on the second insulation layer 20. A second electrode CE20 of a storage capacitor Cst may be located between the second insulation layer 20 and the third insulation layer 30. Also, a first electrode CE10 of the storage capacitor Cst may be located between the first insulation layer 10 and the second insulation layer 20.

A first connection electrode CN1 may be located on the third insulation layer 30. The first connection electrode CN1 may be connected to the drain region DA1 of the transistor TFT through a contact hole passing through the first to third insulation layers 10, 20, and 30.

A fourth insulation layer 40 may be located on the third insulation layer 30. A second connection electrode CN2 may be located on the fourth insulation layer 40. The second connection electrode CN2 may be connected to the first connection electrode CN1 through a contact hole passing through the fourth insulation layer 40. A fifth insulation layer 50 may be located on the fourth insulation layer 40 to cover the second connection electrode CN2. A laminated structure of the first insulation layer 10 to the fifth insulation layer 50 is merely an example, and additional conductive layers and insulation layers may be further located in addition to the first insulation layer 10 to the fifth insulation layer 50.

Each of the fourth insulation layer 40 and the fifth insulation layer 50 may be an organic layer. For example, the organic layer may include a general purpose polymer, such as benzocyclobutene (BCB), polyimide, hexamethyldisiloxane (HMDSO), polymethylmethacrylate (PMMA), or polystyrene (PS), a polymer derivative having a phenolic group, an acrylic polymer, an imide polymer, an aryl ether polymer, an amide polymer, a fluorine polymer, a p-xylene polymer, a vinyl alcohol polymer, and/or a mixture thereof.

The light-emitting element LD may include a first electrode AE (or pixel electrode), a light-emitting layer EL, and a second electrode CE (or common electrode). The first electrode AE may be located on the fifth insulation layer 50. The first electrode AE may be a (semi) transmissive electrode or a reflective electrode.

A pixel-defining layer PDL may be located on the fifth insulation layer 50. According to one or more embodiments, the pixel-defining layer PDL may have a light absorption property, and may have, for example, a black color. The pixel-defining layer PDL may include a black coloring agent. The black coloring agent may include a black pigment and a black dye. The black coloring agent may include carbon black, metal, such as chrome, or an oxide thereof. The pixel-defining layer PDL may correspond to a light-shielding pattern having a light-shielding characteristic.

The pixel-defining layer PDL may cover a portion of the first electrode AE (e.g., anode). For example, an opening PDL-OP for exposing a portion of the first electrode AE may be defined in the pixel-defining layer PDL. The opening PDL-OP of the pixel-defining layer PDL may define the light-emitting area LA.

The pixel-defining layer PDL may increase a distance between an edge of the first electrode AE and the second electrode CE (e.g., cathode). Thus, the pixel-defining layer PDL may serve to reduce or prevent the likelihood of an arc being generated at the edge of the first electrode AE.

In one or more embodiments, a hole control layer may be located between the first electrode AE and the light-emitting layer EL. The hole control layer may include a hole transport layer, and further may include a hole injection layer. An electron control layer may be located between the light-emitting layer EL and the second electrode CE. The electron control layer may include an electron transport layer, and may further include an electron injection layer.

The encapsulation layer TFE may be located on the display element layer DP-ED. The encapsulation layer TFE may protect the display element layer DP-ED from moisture, oxygen, and/or foreign substances, such as dust particles. The encapsulation layer TFE may include at least one inorganic layer and at least one organic layer. The encapsulation layer TFE includes a laminated structure of the inorganic layer and the organic layer. A configuration of the encapsulation layer TFE will be described later in more detail.

The input sensor IS may be located on the display panel DP. The input sensor IS may include a first sensor insulation layer IS-IL1, a first sensor conductive layer IS-CL1, a second sensor insulation layer IS-IL2, a second sensor conductive layer IS-CL2, and a third sensor insulation layer IS-IL3. The first sensor insulation layer IS-IL1 may be located directly on the encapsulation layer TFE.

In one or more embodiments of the present disclosure, the first sensor insulation layer IS-IL1 and/or the third sensor insulation layer IS-IL3 may be omitted. When the first sensor insulation layer IS-IL1 is omitted, the first sensor conductive layer IS-CL1 may be located directly on an uppermost insulation layer of the encapsulation layer TFE. The third sensor insulation layer IS-IL3 may be replaced by an adhesive layer or an insulation layer of the anti-reflector RL located on the input sensor IS.

The first sensor conductive layer IS-CL1 may include first conductive patterns, and the second sensor conductive layer IS-CL2 may include second conductive patterns. The first conductive pattern IS-CL1 is located on the first sensor insulation layer IS-IL1. The second conductive pattern IS-CL2 is located on the second sensor insulation layer IS-IL2. Hereinafter, the first sensor conductive layer IS-CL1 and the first conductive patterns are indicated by the same reference numeral, and the second sensor conductive layer IS-CL2 and the second conductive patterns are indicated by the same reference numeral.

Each of the first conductive patterns IS-CL1 and the second conductive patterns IS-CL2 may have a single-layered structure or a multi-layered structure in which a plurality of layers are laminated in the third direction DR3. The conductive layer having the multi-layered structure may include at least two of the transparent conductive layers or the metal layers. The conductive pattern having the multi-layered structure may include metal layers containing metals different from each other. The transparent conductive layer may include an indium tin oxide (ITO), an indium zinc oxide (IZO), a zinc oxide (ZnO), an indium tin zinc oxide (ITZO), PEDOT, a metal nano-wire, and/or graphene. The metal layer may include molybdenum, silver, titanium, copper, aluminum, and/or an alloy thereof.

Each of the first conductive patterns IS-CL1 and the second conductive patterns IS-CL2 may have a thickness of about 0.1 μm or more and about 1 μm or less. When each of the first conductive patterns IS-CL1 and the second conductive patterns IS-CL2 has a thickness that is less than about 0.1 μm, as line resistance increases, an input detection performance of the input sensor IS may decrease. When each of the first conductive patterns IS-CL1 and the second conductive patterns IS-CL2 has a thickness that is greater than about 1 μm, as a thickness of the input sensor IS excessively increases, a total thickness of the display device DD (refer to FIG. 1A) may increase, and folding characteristics may be degraded.

Each of the first sensor insulation layer IS-IL1 to the third sensor insulation layer IS-IL3 may include an inorganic layer or an organic layer. Each of the first sensor insulation layer IS-IL1 to the third sensor insulation layer IS-IL3 may include an inorganic layer. The inorganic material may include a silicon oxide, a silicon nitride, or a silicon oxynitride.

In one or more embodiments of the present disclosure, at least one of the first sensor insulation layer IS-IL1, the second sensor insulation layer IS-IL2, or the third sensor insulation layer IS-IL3 may be an organic layer. For example, the third sensor insulation layer IS-IL3 may include an organic layer. The organic layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin.

The anti-reflector RL may be located on the input sensor IS. The anti-reflector RL may include a light-shielding pattern BM, a color filter CF, and a planarization layer OC. In one or more embodiments of the present disclosure, the light-shielding pattern BM may be omitted.

The light-shielding pattern BM may be made of various light absorption materials. However, the present disclosure is not limited thereto. The light-shielding pattern BM may be a layer having a black color. In one or more embodiments, the light-shielding pattern BM may include a black coloring agent. The black coloring agent may include a black pigment and a black dye. The black coloring agent may include carbon black, metal, such as chrome, or an oxide thereof.

The light-shielding pattern BM may overlap the first conductive patterns IS-CL1 and the second conductive patterns IS-CL2 on the plane/in plan view. The light-shielding pattern BM may reduce or prevent external light reflection caused by the first conductive patterns IS-CL1 and the second conductive patterns IS-CL2. An opening BM-OP may be defined in the light-shielding pattern BM. The opening BM-OP of the light-shielding pattern BM may overlap the first electrode AE, and may have an area that is greater than that of the opening PDL-OP of the pixel-defining layer PDL. The opening BM-OP of the light-shielding pattern BM may define a pixel area PXA. The pixel area PXA may be defined as an area through which light generated by the light-emitting element LD is emitted to the outside. As an area of the pixel area PXA increases, luminance of an image may increase.

The color filter CF may overlap at least the pixel area PXA. The color filter CF may further overlap a non-pixel area NPXA. The color filter CF may have a portion located on the light-shielding pattern BM. The color filter CF may transmit light generated from the light-emitting element LD, and may reduce or block external light in a corresponding wavelength. Thus, the color filter CF may reduce external light reflection caused by the first electrode AE or the second electrode CE.

The planarization layer OC may cover the light-shielding pattern BM and the color filter CF. The planarization layer OC may include an organic material and provide a flat top surface.

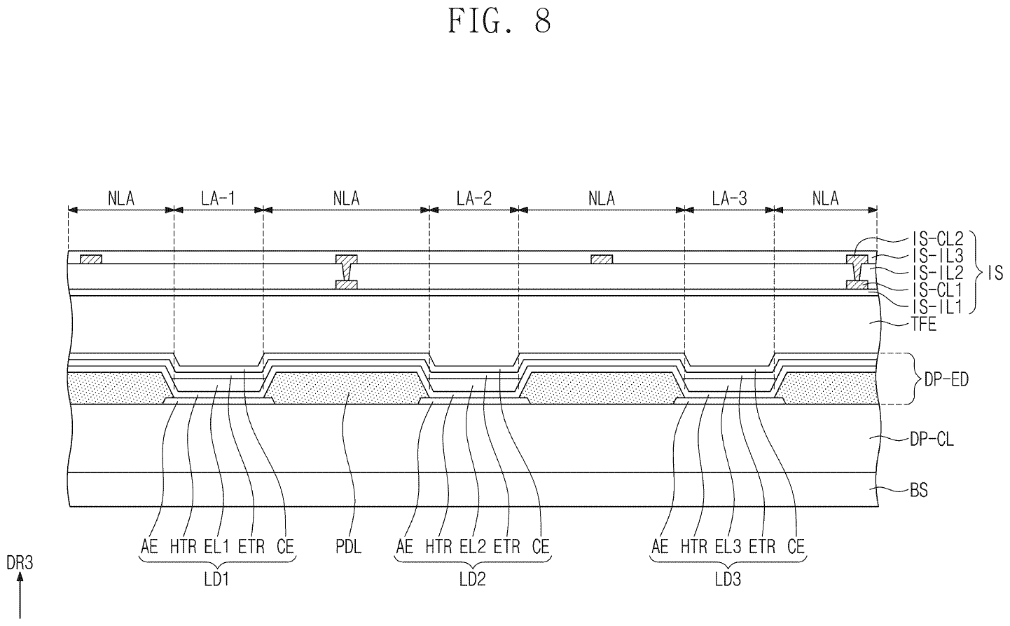

FIG. 8 is an enlarged cross-sectional view illustrating the display module DM according to one or more embodiments of the present disclosure. FIG. 8 illustrates a cross-section corresponding to light-emitting areas LA-1, LA-2, and LA-3, which are adjacent to each other, and the surrounding non-light-emitting area NLA. Here, in FIG. 8, the anti-reflector RL described in FIG. 7 is omitted.

Referring to FIG. 8, the base layer BS may have a single-layered or multi-layered structure. For example, the base layer BS may include a first synthetic resin layer, an intermediate layer having a single-layered or multi-layered structure, and a second synthetic resin layer, which are laminated in order. The intermediate layer may be referred to as a base barrier layer. The intermediate layer may include a silicon oxide (SiOx) layer, and an amorphous silicon (a-Si) layer located on the silicon oxide layer. However, the present disclosure is not limited thereto. For example, the intermediate layer may include at least one of a silicon oxide layer, a silicon nitride layer, a silicon oxynitride layer, or an amorphous silicon layer.

Each of the first and second synthetic resin layers may include a polyimide-based resin. Also, each of the first and second synthetic resin layers may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a term “a”-based resin represents a feature of including a functional group of “α”.

The circuit element layer DP-CL may be located on the base layer BS, and may include a plurality of transistors, in one or more embodiments, each of which may include a control electrode, an input electrode, and an output electrode. For example, the circuit element layer DP-CL may include a switching transistor and a driving transistor for driving light-emitting elements LD1, LD2 and LD3 of the display element layer DP-ED.

The display element layer DP-ED may include the pixel-defining layer PDL and the first to third light-emitting elements LD1, LD2, and LD3. A pixel opening PDL-OP may be defined in the pixel-defining layer PDL. For example, the pixel-defining layer PDL may include an organic light-shielding material or an inorganic light-shielding material, which contains a black pigment or a black dye.

The display panel DP may be divided into a non-light-emitting area NLA and light-emitting areas LA-1, LA-2, and LA-3. Each of the light-emitting areas LA-1, LA-2, and LA-3 may be an area through which light generated by each of the first to third light-emitting elements LD1, LD2, and LD3, respectively, is emitted. The light-emitting areas LA-1, LA-2, and LA-3 may be spaced apart from each other on the plane/in plan view.

Each of the light-emitting areas LA-1, LA-2, and LA-3 may be distinguished by the pixel-defining layer PDL. The non-light-emitting areas NLA may be located between neighboring light-emitting areas LA-1, LA-2, and LA-3, and may correspond to the pixel-defining layers PDL. In this specification, each of the light-emitting areas LA-1, LA-2, and LA-3 may correspond to the pixel. The pixel-defining layer PDL may distinguish the first to third light-emitting elements LD1, LD2, and LD3. Light emitting layers EL1, EL2, and EL3 of the first to third light-emitting elements LD1, LD2, and LD3 may be located in the pixel opening PDL-OP defined in the pixel-defining layer PDL.

The light-emitting areas LA-1, LA-2, and LA-3 may be distinguished into a plurality of groups according to colors of light respectively generated from the first to third light-emitting elements LD1, LD2, and LD3. Three light-emitting areas LA-1, LA-2, and LA-3 respectively emitting red light, green light, and blue light are illustrated as an example in the display panel DP according to one or more embodiments in FIG. 8. For example, the display module DM according to one or more embodiments may include a red light-emitting area LA-1, a green light-emitting area LA-2, and a blue light-emitting area LA-3, which are distinguished from each other.

The first to third light-emitting elements LD1, LD2, and LD3 may be spaced apart from each other in one direction (e.g., first direction DR1) that is perpendicular to the thickness direction DR3. The first to third light-emitting elements LD1, LD2, and LD3 may emit light in different wavelengths. For example, the first light-emitting element LD1 may emit red light, the second light-emitting element LD2 may emit green light, and the third light-emitting element LD3 may emit blue light. That is, the red light-emitting area LA-1, the green light-emitting area LA-2, and the blue light-emitting area LA-3 may correspond to the first light-emitting element LD1, the second light-emitting element LD2, and the third light-emitting element LD3, respectively.

However, the present disclosure is not limited thereto. For example, the first to third light-emitting elements LD1, LD2, and LD3 may emit light in the same wavelength region or at least one light in a different wavelength region. For example, all of the first to third light-emitting elements LD1, LD2, and LD3 may emit blue light.

Each of the light-emitting elements LD1, LD2, and LD3 may include a first electrode AE, a second electrode CE located on the first electrode AE, and a light-emitting layer EL1, EL2, and EL3 located between the first electrode AE and the second electrode CE. The first electrode AE may be exposed from the pixel opening PDL-OP of the pixel-defining layer PDL.

Also, each of the light-emitting elements LD1, LD2, and LD3 may further include a hole control layer HTR and an electron control layer ETR. The hole control layer HTR may be located between the first electrode AE and the light-emitting layer EL1, EL2, and EL3. The electron control layer ETR may be located between the light-emitting layer EL1, EL2, and EL3 and the second electrode CE.

FIG. 8 illustrates one or more embodiments in which the light-emitting layer EL1, EL2, and EL3 of the light-emitting elements LD1, LD2 and LD3 are located in the pixel opening PDL-OP defined in the pixel-defining layer PDL, and the hole control layer HTR, the electron control layer ETR, and the second electrode EL2 are provided as a common layer over all of the light-emitting elements LD1, LD2 and LD3. However, the present disclosure is not limited thereto. For example, unlike as illustrated in FIG. 8, the hole control layer HTR and the electron control layer ETR may be provided by being patterned in the pixel opening PDL-OP defined in the pixel-defining layer PDL. For example, in one or more embodiments, the hole control layer HTR, the light-emitting layer EL1, EL2, and EL3, and the electron control layer ETR of the light-emitting elements LD1, LD2 and LD3 may be patterned by an inkjet printing method.

The first electrode AE may be an anode. However, the present disclosure is not limited thereto. Also, the first electrode AE may be a pixel electrode. The first electrode AE may be a transmissive electrode, a semi-transmissive electrode, or a reflective electrode. The first electrode AE may include at least one selected from Ag, Mg, Cu, Al, Pt, Pd, Au, Ni, Nd, Ir, Cr, Li, Ca, LiF, Mo, Ti, W, In, Sn, or Zn, a compound of at least two selected from the same, a mixture of at least two selected from the same, and an oxide thereof.

When the first electrode AE is the transmissive electrode, the first electrode AE may include a metal oxide, such as, for example, an indium tin oxide (ITO), an indium zinc oxide (IZO), a zinc oxide (ZnO), or an indium tin zinc oxide (ITZO). When the first electrode AE is the semi-transmissive electrode or the reflective electrode, the first electrode AE may include Ag, Mg, Cu, Al, Pt, Pd, Au, Ni, Nd, Ir, Cr, Li, Ca, LiF/Ca (a laminated structure of LiF and Ca), LiF/AI (a laminated structure of LiF and Al), Mo, Ti, or a compound or mixture (e.g., a mixture of Ag and Mg) thereof. Alternatively, the first electrode AE may have a multi-layered structure including a reflective layer or a transflective layer, which is made of the above-described materials, and a transparent conductive layer made of an indium tin oxide (ITO), an indium zinc oxide (IZO), a zinc oxide (ZnO), or an indium tin zinc oxide (ITZO). For example, the first electrode AE may have a three-layered structure of ITO/Ag/ITO. However, the present disclosure is not limited thereto. Also, the first electrode AE may include a combination of two or more metal materials selected from the above-described metal materials, or an oxide of the above-described metal materials. However, the present disclosure is not limited thereto.

The hole control layer HTR may have a single layer made of a single material, a single layer made of a plurality of materials different from each other, or a multi-layered structure including a plurality of layers made of a plurality of materials different from each other. In one or more embodiments, the hole control layer HTR may include at least one of a hole injection layer, a hole transport layer, or an electron stop layer. Also, in one or more embodiments, the hole control layer HTR may further include a light-emitting auxiliary layer for compensating a resonance distance according to a wavelength of light emitted from the light-emitting layers EL1, EL2, and EL3.

The hole control layer HTR may include a phthalocyanine compound, such as copper phthalocyanine, DNTPD(N1,N1′-([1,1′-biphenyl]-4,4′-diyl)bis(N1-phenyl-N4,N4-di-m-tolylbenzene-1,4-diamine)), m-MTDATA(4,4′,4″-[tris(3-methylphenyl)phenylamino]triphenylamine), TDATA(4,4′,4″-Tris(N,N-diphenylamino)triphenylamine), 2-TNATA(4,4′,4″-tris[N(2-naphthyl)-N-phenylamino]-triphenylamine), PEDOT/PSS(Poly(3,4-ethylenedioxythiophene)/Poly(4-styrenesulfonate)), PANI/DBSA(Polyaniline/Dodecylbenzenesulfonic acid), PANI/CSA(Polyaniline/Camphor sulfonicacid), PANI/PSS(Polyaniline/Poly(4-styrenesulfonate)), NPB(N,N′-di(naphthalene-1-yl)-N,N′-diphenyl-benzidine), polyetherketone (TPAPEK) containing triphenylamine, 4-Isopropyl-4′-methyldiphenyliodonium [Tetrakis(pentafluorophenyl)borate], and/or HATCN (dipyrazino[2,3-f: 2′,3′-h]quinoxaline-2,3,6,7,10,11-hexacarbonitrile).

Also, the hole control layer HTR may include a carbazole-based derivative, such as N-phenylcarbazole and/or polyvinylcarbazole, a fluorene-based derivative, TPD (N,N′-bis(3-methylphenyl)-N, N′-diphenyl-[1,1′-biphenyl]-4,4′-diamine), a triphenylamine derivative, such as TCTA (4,4′,4″-tris(N-carbazolyl)triphenylamine), TAPC (4,4′-Cyclohexylidene bis[N, N-bis(4-methylphenyl)benzenamine]), HMTPD (4,4′-Bis[N,N′-(3-tolyl)amino]-3,3′-dimethylbiphenyl), CzSi (9-(4-tert-Butylphenyl)-3,6-bis(triphenylsilyl)-9H-carbazole), CCP (9-phenyl-9H-3,9′-bicarbazole), mCP (1,3-Bis(N-carbazolyl)benzene), or mDCP (1,3-bis(1,8-dimethyl-9H-carbazol-9-yl)benzene).

The light-emitting layer EL1, EL2, and EL3 may have a single-layered structure made of a single material, a single-layered structure made of a plurality of materials, which are different from each other, or a multi-layered structure including a plurality of layers made of a plurality of materials, which are different from each other. The light-emitting layer EL1, EL2, and EL3 may include an anthracene derivative, a pyrene derivative, a fluoranthene derivative, a chrysene derivative, a dihydrobenzanthracene derivative, or a triphenylene derivative.

For example, the light-emitting layer EL1, EL2, and EL3 may include one host and one dopant. Alternatively, the light-emitting layer EL1, EL2, and EL3 may include two or more hosts and dopants.

The light-emitting layer EL3 of the third light-emitting element LD3, which emits blue light, may emit thermally activated delayed fluorescence (TADF) or phosphorescence. The light-emitting layer EL3 of the third light-emitting element LD3 may include a TADF material and/or a phosphorescent material. The third light-emitting element LD3 containing the TADF material and/or the phosphorescent material may exhibit suitable light-emitting efficiency.

The light-emitting layer EL1, EL2, and EL3 may include, as a well-known dopant material, a styryl derivative (e.g., 1, 4-bis[2-(3-N-ethylcarbazolyl)vinyl]benzene(BCzVB), 4-(di-p-tolylamino)-4′-[(di-p-tolylamino)styryl]stilbene(DPAVB), N-(4-((E)-2-(6-((E)-4-(diphenylamino)styryl)naphthalen-2-yl)vinyl)phenyl)-N-phenylbenzenamine(N-BDAVBi)), 4,4′-bis[2-(4-(N,N-diphenylamino)phenyl)vinyl]biphenyl(DPAVBi), perylene and/or a perylene derivative (e.g., 2, 5, 8, 11-Tetra-t-butylperylene (TBP)), pyrene and/or a pyrene derivative (e.g., 1, 1-dipyrene, 1, 4-dipyrenylbenzene, 1, 4-Bis(N, N-Diphenylamino)pyrene).

The light-emitting layer EL1, EL2, and EL3 may include a well-known phosphorescent dopant material. For example, as the phosphorescent dopant, a metal complex including iridium (Ir), platinum (Pt), osmium (Os), gold (Au), titanium (Ti), zirconium (Zr), hafnium (Hf), europium (Eu), terbium (Tb), or thulium (Tm) may be used. For example, FlrPic(iridium(III) bis(4,6-difluorophenylpyridinato-N,C2′)picolinate), FIr6(Bis(2,4-difluorophenylpyridinato)-tetrakis(1-pyrazolyl)borate iridium(Ill)), or PtOEP(platinum octaethyl porphyrin) may be used as the phosphorescent dopant. However, the present disclosure is not limited thereto.

In one or more embodiments, the electron control layer ETR may include at least one of an electron stop layer, a hole transport layer, or a hole injection layer. The electron control layer ETR may have a single layer made of a single material, a single layer made of a plurality of materials different from each other, or a multi-layered structure including a plurality of layers made of a plurality of materials different from each other.

The electron control layer ETR may include an anthracene-based compound. However, the present disclosure is not limited thereto. For example, the electron control layer ETR may include Alq3(Tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, TPBi(1,3,5-Tri(1-phenyl-1H-benzo[d]imidazol-2-yl)benzene), BCP(2,9-Dimethyl-4,7-diphenyl-1,10-phenanthroline), Bphen(4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1′-Biphenyl-4-olato)aluminum), Bebq2(berylliumbis(benzoquinolin-10-olate)), ADN(9,10-di(naphthalene-2-yl)anthracene), BmPyPhB(1,3-Bis[3,5-di(pyridin-3-yl)phenyl]benzene), and/or a mixture thereof.

Also, the electron control layer ETR may include a halide metal, such as LiF, NaCl, CsF, RbCl, RbI, CuI, and/or KI, a lanthanide metal, such as Yb, or a co-deposition material of the above-described halide metal and/or lanthanide metal. For example, the electron control layer ETR may include the co-deposition material, such as KI:Yb, RbI:Yb, and/or LiF:Yb. The electron control layer ETR may be made of a metal oxide, such as Li2O and/or BaO or Liq(8-hydroxyl-Lithium quinolate). However, the present disclosure is not limited thereto. The electron control layer ETR may be made of a material in which the electron transport material and an insulating organo metal salt are mixed. The organo metal salt may be a material having an energy band gap of about 4 eV or more. For example, the organo metal salt may include metal acetate, metal benzoate, metal acetoacetate, metal acetylacetonate, or metal stearate.

The second electrode CE may be a common electrode. Although the second electrode CE may be a cathode, the present disclosure is not limited thereto. The second electrode CE may include at least one selected from Ag, Mg, Cu, Al, Pt, Pd, Au, Ni, Nd, Ir, Cr, Li, Ca, LiF, Mo, Ti, W, In, Sn, or Zn, a compound of at least two selected from the same, a mixture of at least two selected from the same, and/or an oxide thereof.

In one or more embodiments, the light-emitting elements LD1, LD2, and LD3 may further include a capping layer located on the second electrode CE. The capping layer may be an organic layer or an inorganic layer. For example, when the capping layer includes an inorganic material, the inorganic material may include an alkali metal compound, such as LiF, and/or an alkali earth metal compound, such as MgF2, SiON, SiNX, and/or SiOy. For example, when the capping layer CPL includes an organic material, the organic material may include α-NPD, NPB, TPD, m-MTDATA, Alq3, CuPc, TPD15(N4,N4,N4′,N4′-tetra (biphenyl-4-yl) biphenyl-4,4′-diamine), and/or TCTA(4,4′, 4″-Tris (carbazol-9-yl) triphenylamine), or may include an epoxy resin or acrylate, such as methacrylate.

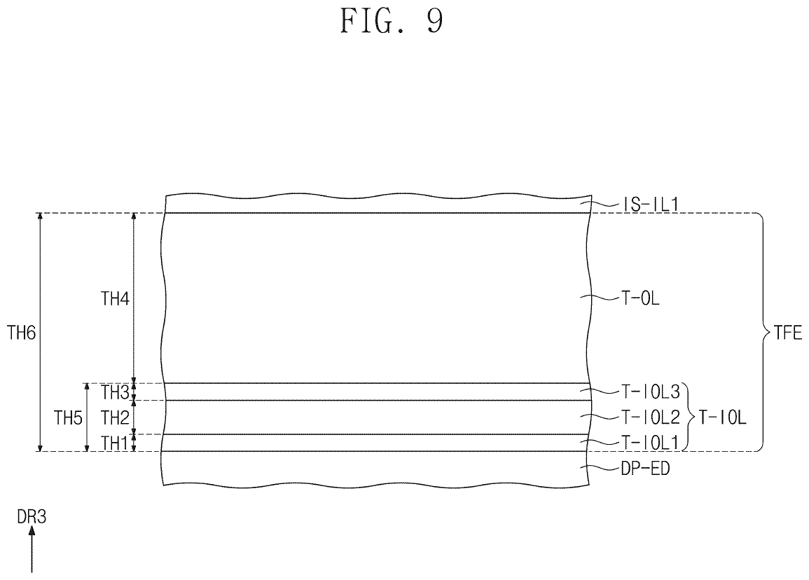

In one or more embodiments, the encapsulation layer TFE may cover the display element layer DP-ED. The encapsulation layer TFE may be a thin-film encapsulation layer. The encapsulation layer TFE includes at least one inorganic encapsulation layer or an organic encapsulation layer located on the inorganic encapsulation layer. The encapsulation layer TFE will be described in detail later with reference to FIG. 9.

FIG. 9 is a cross-sectional view illustrating a partial configuration of the display module according to one or more embodiments of the present disclosure. FIG. 9 illustrates a cross-sectional laminated structure of the encapsulation layer TFE and layers adjacent to upper and lower portions of the encapsulation layer TFE. A description on the encapsulation layer TFE in FIG. 9 may be applied to the encapsulation layer TFE of the display panel DP in FIGS. 7 and 8.

Referring to FIG. 9, the encapsulation layer TFE includes an inorganic encapsulation layer T-IOL and an organic encapsulation layer T-OL. The encapsulation layer TFE may include the inorganic encapsulation layer T-IOL located on the display element layer DP-ED, and the organic encapsulation layer T-OL located on the inorganic encapsulation layer T-IOL.

The inorganic encapsulation layer T-IOL may be located on the display element layer DP-ED to protect the display element layer DP-ED from moisture and/or oxygen. The inorganic encapsulation layer T-IOL may include a material having a high refractive index. The inorganic encapsulation layer T-IOL may include at least one of a silicon oxide, a silicon nitride, or a silicon oxynitride.

The inorganic encapsulation layer T-IOL may include a first inorganic encapsulation layer T-IOL1, a second inorganic encapsulation layer T-IOL2, and a third inorganic encapsulation layer T-IOL3, which are laminated in order. The first inorganic encapsulation layer T-IOL1 may be located on the display element layer DP-ED, the second inorganic encapsulation layer T-IOL2 may be located on the first inorganic encapsulation layer T-IOL1, and the third inorganic encapsulation layer T-IOL3 may be located on the second inorganic encapsulation layer T-IOL2.

The first inorganic encapsulation layer T-IOL1 may be located directly on the display element layer DP-ED. The first inorganic encapsulation layer T-IOL1 may be located directly on the light-emitting elements LD (LD1, LD2, LD3) described above in FIGS. 7 and 8 to cover the light-emitting elements LD (LD1, LD2, LD3). The first inorganic encapsulation layer T-IOL1 may be located directly on the second electrode CE of the light-emitting elements LD (LD1, LD2, LD3). If the light-emitting elements LD (LD1, LD2, LD3) further include a capping layer, the first inorganic encapsulation layer T-IOL1 may be located directly on the capping layer.

The second inorganic encapsulation layer T-IOL2 may be directly located on the first inorganic encapsulation layer T-IOL1. The third inorganic encapsulation layer T-IOL3 may be located directly on the second inorganic encapsulation layer T-IOL2. The first inorganic encapsulation layer T-IOL1, the second inorganic encapsulation layer T-IOL2, and the third inorganic encapsulation layer T-IOL3 may have a continuously laminated layered structure without another layer located therebetween.

Each of the first inorganic encapsulation layer T-IOL1, the second inorganic encapsulation layer T-IOL2, and the third inorganic encapsulation layer T-IOL3 may be made of the same precursor material. Each of the first inorganic encapsulation layer T-IOL1, the second inorganic encapsulation layer T-IOL2, and the third inorganic encapsulation layer T-IOL3 may be made of a silicon precursor material. Each of the first inorganic encapsulation layer T-IOL1, the second inorganic encapsulation layer T-IOL2, and the third inorganic encapsulation layer T-IOL3 may include the same material. Each of the first inorganic encapsulation layer T-IOL1, the second inorganic encapsulation layer T-IOL2, and the third inorganic encapsulation layer T-IOL3 may include at least one of a silicon nitride, a silicon oxynitride, or a silicon oxide. For example, all of the first inorganic encapsulation layer T-IOL1, the second inorganic encapsulation layer T-IOL2, and the third inorganic encapsulation layer T-IOL3 may be made of a silicon nitride.

Each of the first inorganic encapsulation layer T-IOL1, the second inorganic encapsulation layer T-IOL2, and the third inorganic encapsulation layer T-IOL3 has a high refractive index. In one or more embodiments, each of the first inorganic encapsulation layer T-IOL1, the second inorganic encapsulation layer T-IOL2, and the third inorganic encapsulation layer T-IOL3 may have a refractive index of about 1.90 or more to about 2.10 or less. Also, each of the first inorganic encapsulation layer T-IOL1, the second inorganic encapsulation layer T-IOL2, and the third inorganic encapsulation layer T-IOL3 may have a refractive index of about 1.90 or more to about 2.10 or less in a wavelength region of about 430 nm or more to about 490 nm or less.

Each of the first inorganic encapsulation layer T-IOL1, the second inorganic encapsulation layer T-IOL2, and the third inorganic encapsulation layer T-IOL3 may have a refractive index of about 1.90 or more to about 2.10 or less in a wavelength range of a blue region.

The second inorganic encapsulation layer T-IOL2 may have a thickness TH2 that is greater than each of a thickness TH1 of the first inorganic encapsulation layer T-IOL1 and a thickness TH3 of the third inorganic encapsulation layer T-IOL3. The thickness TH1 of the first inorganic encapsulation layer T-IOL1 may be substantially equal to the thickness TH3 of the third inorganic encapsulation layer T-IOL3. The second inorganic encapsulation layer T-IOL2 may have the thickness TH2 of about 1500 Å or more to about 2000 Å or less. Each of the thickness TH1 of the first inorganic encapsulation layer T-IOL1 and the thickness TH3 of the third inorganic encapsulation layer T-IOL3 may be about 1 Å or more to about 10 Å or less. The inorganic encapsulation layer T-IOL may have a total thickness TH5 of about 1550 Å or more to about 2010 Å or less.

The second inorganic encapsulation layer T-IOL2 may have the thickness TH2 equal to or greater than about 100 times of each of the thickness TH1 of the first inorganic encapsulation layer T-IOL1 and the thickness TH3 of the third inorganic encapsulation layer T-IOL3. A process for fabricating the second inorganic encapsulation layer T-IOL2 may be different from a process for fabricating each of the first inorganic encapsulation layer T-IOL1 and the third inorganic encapsulation layer T-IOL3 so that the second inorganic encapsulation layer T-IOL2 has the thickness equal to or greater than about 100 times of each of the thickness of the first inorganic encapsulation layer T-IOL1 and the thickness of the third inorganic encapsulation layer T-IOL3.

The second inorganic encapsulation layer T-IOL2 having the great thickness may have planarization characteristics. That is, the second inorganic encapsulation layer T-IOL2 may have a planarized top surface. The second inorganic encapsulation layer T-IOL2 may planarize a stepped portion generated by foreign substances located therebelow, or a stepped portion generated by the pixel-defining layer PDL in FIGS. 7 and 8, to provide the planarized top surface.

The second inorganic encapsulation layer T-IOL2 may have middle moisture barrier characteristics. The second inorganic encapsulation layer T-IOL2 may have a water vapor transmission rate of about 1×10⁻⁴ g/m²·day or more to about 9×10⁻⁴ g/m²·day or less.

The organic encapsulation layer T-OL is located on the inorganic encapsulation layer T-IOL. The organic encapsulation layer T-OL may be located directly on the third inorganic encapsulation layer T-IOL3. The organic encapsulation layer T-OL may protect the display element layer DP-ED from foreign substances, such as dust particles. The organic encapsulation layer T-OL may have a refractive index less than that of the inorganic encapsulation layer T-IOL. The organic encapsulation layer T-OL may include an acrylate-based compound, an epoxy-based compound, and a vinyl-based compound. The organic encapsulation layer T-OL may include a photopolymerizable organic material. However, the present disclosure is not limited thereto.

The organic encapsulation layer T-OL may have a thickness TH4 that is greater than the thickness TH5 of the inorganic encapsulation layer T-IOL. For example, the organic encapsulation layer T-OL may have the thickness TH4 of about 3 μm or more to about 8 μm or less. The organic encapsulation layer T-OL having a thickness less than about 3 μm may not sufficiently protect the display element layer DP-ED from foreign substances. Also, the organic encapsulation layer T-OL having a thickness greater than about 8 μm may unsuitably reduce output of light emitted from the display element layer DP-ED. The organic encapsulation layer T-OL having the thickness TH4 of about 3 μm to about 8 μm may exhibit suitable sealing reliability and contribute to maintain a satisfactory display quality.

In the encapsulation layer TFE according to one or more embodiments, the organic encapsulation layer T-OL has a relatively low dielectric constant. The organic encapsulation layer T-OL may include a material having a low dielectric constant. In one or more embodiments, the organic encapsulation layer T-OL has a dielectric constant Dk of about 1.0 or more to about 2.5 or less.

The organic encapsulation layer T-OL may include a polymer material having a high molecular anisotropy, and thus may have a dielectric constant value that is less than that of a typical organic layer including a polymer having a low molecular anisotropy. In the encapsulation layer TFE according to one or more embodiments, the organic encapsulation layer T-OL may include a (meth)acrylate-based polymer, an epoxy-based polymer, and/or a vinyl-based polymer. The (meth)acrylate-based polymer represents an acrylate-based polymer or a methacrylate-based polymer.

The organic encapsulation layer T-OL may include a polymer material having a high molecular anisotropy, and may have low dielectric constant characteristics by including an appropriate free volume in a molecule of the polymer.

At the same time, the organic encapsulation layer T-OL may have strength characteristics to be used for the encapsulation layer TFE. The encapsulation layer TFE according to one or more embodiments may reduce a noise of the input sensor IS (refer to FIG. 7) located on the encapsulation layer TFE due to the low dielectric constant characteristics of the organic encapsulation layer T-OL, and may improve touch sensitivity of the input sensor IS. That is, the encapsulation layer TFE according to one or more embodiments may reduce capacitance between the second electrode CE located below the encapsulation layer TFE and the sensor conductive layers IS-CL1 and IS-CL2 (refer to FIG. 7) located on the encapsulation layer TFE by including the organic encapsulation layer T-OL having the low dielectric constant characteristics to improve the touch sensitivity of the input sensor IS.

A top surface of the organic encapsulation layer T-OL may define an uppermost surface of the encapsulation layer TFE. In the encapsulation layer TFE, another component may not be located on the organic encapsulation layer T-OL. The input sensor IS (refer to FIG. 7) may be located directly on the organic encapsulation layer T-OL. As illustrated in FIG. 9, the first sensor insulation layer IS-IL1 of the input sensor IS may be located directly on the organic encapsulation layer T-OL. In the display panel DP (refer to FIG. 7) according to one or more embodiments, another component may not be located on the organic encapsulation layer T-OL included in the encapsulation layer TFE.

The encapsulation layer TFE including the inorganic encapsulation layer T-IOL and the organic encapsulation layer T-OL may have a total thickness TH6 of about 3.2 μm or more to about 8.2 μm or less. The encapsulation layer TFE according to one or more embodiments may have a structure having a reduced total thickness because the encapsulation layer TFE does not include an additional inorganic encapsulation layer located on the organic encapsulation layer T-OL, unlike a typical encapsulation layer structure. Thus, when the encapsulation layer TFE is applied to the foldable display device DD as illustrated in FIGS. 1A, 1B, and 1C, the likelihood of a crack generated by the folding operation may be reduced or prevented, and a crack may not be generated although a portion of the display panel DP (refer to FIG. 6) is bent.

The encapsulation layer TFE included in the display panel according to one or more embodiments may include the inorganic encapsulation layer T-IOL having a three-layered structure, and the organic encapsulation layer T-OL located on the inorganic encapsulation layer T-IOL has low dielectric constant characteristics. Thus, when the encapsulation layer TFE is applied to the display panel, the encapsulation layer TFE may reduce the total thickness, and may improve the touch sensitivity of the input sensor IS located thereabove. For example, because the encapsulation layer TFE includes a first encapsulation layer T-IOL1, a second encapsulation layer T-IOL2, and a third encapsulation layer T-IOL3, which are laminated in order, and because the second encapsulation layer T-IOL2 has a structure having a relatively great thickness, the encapsulation layer TFE may have suitable barrier characteristics, and may reduce the total thickness, although an additional inorganic encapsulation layer is not provided on the organic encapsulation layer T-OL. Although the thickness of the encapsulation layer TFE is reduced, because the organic encapsulation layer T-OL includes a material having a low dielectric constant Dk, a noise of the input sensor IS (refer to FIG. 7) located on the encapsulation layer TFE may be reduced, and the touch sensitivity of the input sensor IS may be improved.

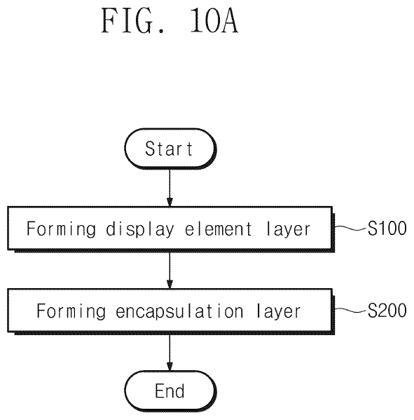

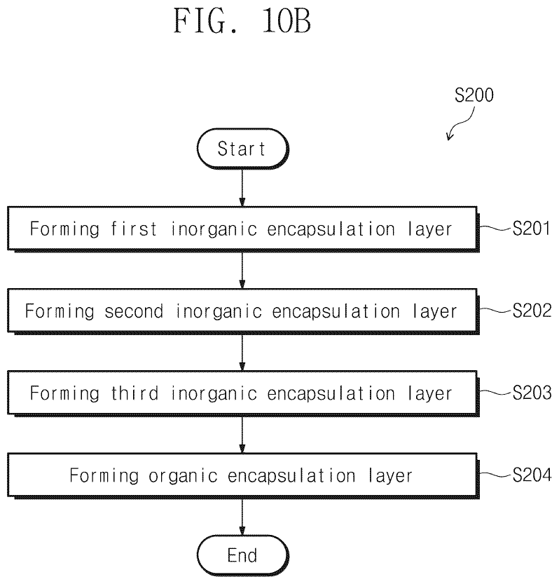

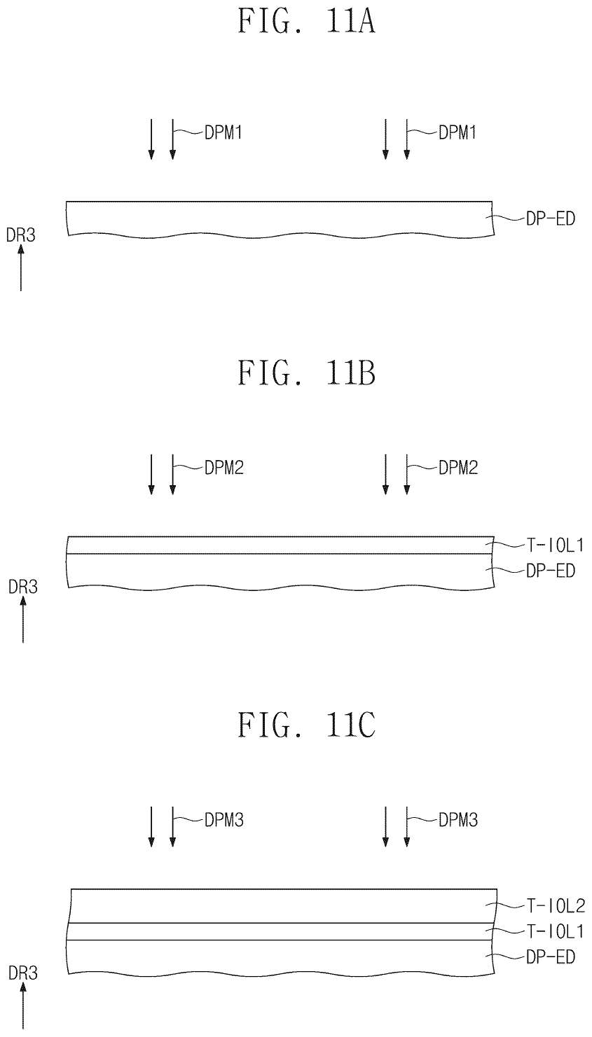

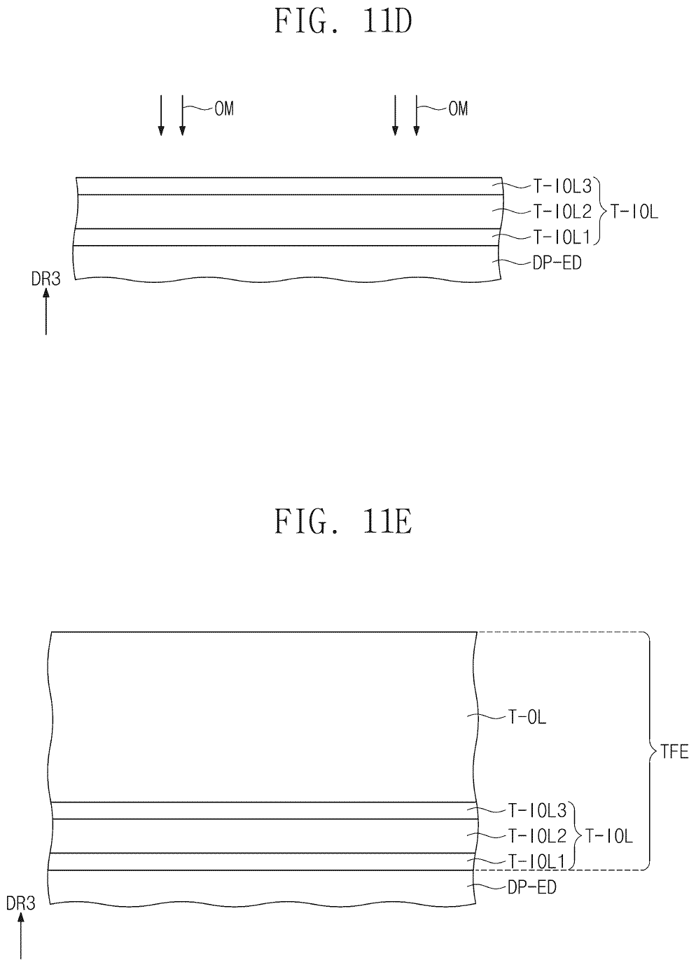

FIG. 10A is a flowchart representing a method for manufacturing a display panel according to one or more embodiments of the present disclosure. FIG. 10B is a flowchart representing some processes of the method for manufacturing the display panel according to one or more embodiments of the present disclosure. FIGS. 11A, 11B, 11C, 11D, and 11E are cross-sectional views respectively illustrating the some processes of the method of manufacturing the display panel according to one or more embodiments of the present disclosure. FIG. 10B shows each process included in the processes of forming an encapsulation layer of the method for manufacturing the display panel according to one or more embodiments of the present disclosure. FIGS. 11A, 11B, 11C, 11D, and 11E respectively illustrate cross-sections of the processes of forming the encapsulation layer of the method for manufacturing the display panel according to one or more embodiments of the present disclosure.

Referring to FIG. 10A, the method for manufacturing the display panel according to one or more embodiments includes a process S100 of forming a display element layer including a pixel-defining layer and a light-emitting element, and a process S200 of forming an encapsulation layer covering the light-emitting element located on the display element layer. Referring to FIG. 10B, the process S200 of forming the encapsulation layer according to one or more embodiments includes: a process S201 of forming a first inorganic encapsulation layer on a display element layer; a process S202 of forming a second inorganic encapsulation layer on the first inorganic encapsulation layer; a process S203 of forming a third inorganic encapsulation layer on the second inorganic encapsulation layer; and a process S204 of forming an organic encapsulation layer on the third inorganic encapsulation layer. A description on a configuration of each of the display element layer and the encapsulation layer may be the same as that described in FIGS. 5 to 9.

FIGS. 11A, 11B, 11C, 11D, and 11E sequentially illustrate the processes for manufacturing the encapsulation layer on a cross-section corresponding FIG. 9.

Referring to FIGS. 10B, 11A, and 11B, the process S200 of forming the encapsulation layer in the method for manufacturing the display panel according to one or more embodiments includes the process S201 of forming a first inorganic encapsulation layer T-IOL1 on a display element layer DP-ED.

The first inorganic encapsulation layer T-IOL1 may be formed by providing a first inorganic deposition material DPM1 on a top surface of the display element layer DP-ED. The first inorganic encapsulation layer T-IOL1 may be formed directly on the display element layer DP-ED. The first inorganic encapsulation layer T-IOL1 may be formed directly on the light-emitting elements LD (LD1, LD2, LD3) described above in FIGS. 7 and 8 to cover the light-emitting elements LD (LD1, LD2, LD3). The first inorganic encapsulation layer T-IOL1 may be formed directly on the second electrode CE of the light-emitting elements LD (LD1, LD2, LD3). When the light-emitting elements LD (LD1, LD2, LD3) further include a capping layer, the first inorganic encapsulation layer T-IOL1 may be formed directly on the capping layer.

Referring to FIGS. 10B, 11B, and 11C, the process S200 of forming the encapsulation layer in the method for manufacturing the display panel according to one or more embodiments includes the process S202 of forming a second inorganic encapsulation layer T-IOL2 on the first inorganic encapsulation layer T-IOL1.

The second inorganic encapsulation layer T-IOL2 may be formed by providing a second inorganic deposition material DPM2 on a top surface of the first inorganic encapsulation layer T-IOL1. The second inorganic encapsulation layer T-IOL2 may be formed directly on the first inorganic encapsulation layer T-IOL1.

Referring to FIGS. 10B, 11C, and 11D, the process S200 of forming the encapsulation layer in the method for manufacturing the display panel according to one or more embodiments includes the process S203 of forming a third inorganic encapsulation layer T-IOL3 on the second inorganic encapsulation layer T-IOL2.

The third inorganic encapsulation layer T-IOL3 may be formed by providing a third inorganic deposition material DPM3 on a top surface of the second inorganic encapsulation layer T-IOL2. The third inorganic encapsulation layer T-IOL3 may be formed directly on the second inorganic encapsulation layer T-IOL2.

Each of the first inorganic encapsulation layer T-IOL1, the second inorganic encapsulation layer T-IOL2, and the third inorganic encapsulation layer T-IOL3 may be made of the same precursor material. That is, the first inorganic deposition material DPM1, the second inorganic deposition material DPM2, and the third inorganic deposition material DPM3, which form the first inorganic encapsulation layer T-IOL1, the second inorganic encapsulation layer T-IOL2, and the third inorganic encapsulation layer T-IOL3, respectively, may be the same as each other. Each of the first inorganic deposition material DPM1, the second inorganic deposition material DPM2, and the third inorganic deposition material DPM3 may include the same silicon precursor. In one or more embodiments, each of the first inorganic deposition material DPM1, the second inorganic deposition material DPM2, and the third inorganic deposition material DPM3 may include a silicon nitride. Processes for forming the first inorganic encapsulation layer T-IOL1, the second inorganic encapsulation layer T-IOL2, and the third inorganic encapsulation layer T-IOL3 may be performed as a continuous process in the same chamber as the first inorganic encapsulation layer T-IOL1, the second inorganic encapsulation layer T-IOL2, and the third inorganic encapsulation layer T-IOL3 are made of the same precursor material. However, the present disclosure is not limited thereto. The processes for forming the first inorganic encapsulation layer T-IOL1, the second inorganic encapsulation layer T-IOL2, and the third inorganic encapsulation layer T-IOL3 may be performed in different chambers.

As described above, the second inorganic encapsulation layer T-IOL2 may have a thickness that is greater than each of a thickness of the first inorganic encapsulation layer T-IOL1 and a thickness of the third inorganic encapsulation layer T-IOL3. The second inorganic encapsulation layer T-IOL2 may have a thickness equal to or greater than about 100 times of each of the thickness of the first inorganic encapsulation layer T-IOL1 and the thickness of the third inorganic encapsulation layer T-IOL3. The process for forming the second inorganic encapsulation layer T-IOL2 may be different from the process for forming each of the first inorganic encapsulation layer T-IOL1 and the third inorganic encapsulation layer T-IOL3 so that the second inorganic encapsulation layer T-IOL2 has the thickness equal to or greater than about 100 times of each of the thickness of the first inorganic encapsulation layer T-IOL1 and the thickness of the third inorganic encapsulation layer T-IOL3.

In one or more embodiments, each of the process S201 of forming the first inorganic encapsulation layer T-IOL1 and the process S203 of forming the third inorganic encapsulation layer T-IOL3 may be performed through a plasma-enhanced atomic layer deposition (PEALD) or physical vapor deposition process. For example, each of the process S201 of forming the first inorganic encapsulation layer T-IOL1 and the process S203 of forming the third inorganic encapsulation layer T-IOL3 may be performed through a plasma-enhanced atomic layer deposition (PEALD), sputtering, thermal evaporation, or E-beam evaporation. The process S202 of forming the second inorganic encapsulation layer T-IOL2 may be performed through a plasma-enhanced chemical vapor deposition (PECVD) process. Each of the first inorganic encapsulation film T-IOL1 and the third inorganic encapsulation film T-IOL3 may be formed to have a relatively thin thickness and to have relatively high barrier characteristics through the PEALD or physical vapor deposition process, and the second inorganic encapsulation layer T-IOL2 may be formed to have a relatively great thickness through the PECVD process.

Referring to FIGS. 10B, 11D, and 11E, the process S200 of forming the encapsulation layer in the method for manufacturing the display panel according to one or more embodiments includes the process S204 of forming an organic encapsulation layer T-OL on the third inorganic encapsulation layer T-IOL3.

The organic encapsulation layer T-OL may be formed by providing an organic material OM onto a top surface of the third inorganic encapsulation layer T-IOL3. The organic encapsulation layer T-OL may be formed directly on the third inorganic encapsulation layer T-IOL3.

The organic material OM may be provided onto the third inorganic encapsulation layer T-IOL3 through a process, such as inkjet printing, screen printing, spin coating, and slit coating. The organic material OM may have a low dielectric constant. In one or more embodiments, the organic material OM has a dielectric constant Dk of about 1.0 or more to about 2.5 or less. The organic material OM may include a polymer material having a high molecular anisotropy, and thus may have a dielectric constant value that is less than that of a typical organic layer including a polymer having a low molecular anisotropy. In the method for manufacturing the display panel according to one or more embodiments, the organic material OM may include a (meth)acrylate-based polymer, an epoxy-based polymer, and/or a vinyl-based polymer.

In the method for manufacturing the display panel according to one or more embodiments, the process of forming the encapsulation layer TFE may be completed after the process of forming the organic encapsulation layer T-OL, and the top surface of the organic encapsulation layer T-OL may define the top surface of the encapsulation layer TFE. In the encapsulation layer TFE, another component might not be additionally formed on the organic encapsulation layer T-OL. After the process of forming the organic encapsulation layer T-OL, the input sensor IS (refer to FIG. 7) may be formed on the organic encapsulation layer T-OL. The first sensor insulation layer IS-IL1 may be formed directly on the organic encapsulation layer T-OL. The method for manufacturing the display panel according to one or more embodiments may not include the process of forming the additional inorganic encapsulation layer on the organic encapsulation layer T-OL.

In the method for manufacturing the display panel according to one or more embodiments, because the process of forming the encapsulation layer TFE includes the process of forming the inorganic encapsulation layer T-IOL having the three-layered structure and the process of forming the organic encapsulation layer T-OL located on the inorganic encapsulation layer T-IOL, the display panel formed through the method for manufacturing the display panel may have the reduced total thickness, and the touch sensitivity of the input sensor may be improved when the input sensor is formed on the display panel thereafter.

According to embodiments of the present disclosure, the flexible characteristics may be improved as the thickness of the display panel is reduced, and the sensing performance of the input sensor may be improved.

According to embodiments of the present disclosure, the display panel having the reduced thickness through the simplified process may be manufactured.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Hence, the real protective scope of the present disclosure shall be determined by the technical scope of the accompanying claims, with functional equivalents thereof to be included therein.

What is claimed is:

1. A display panel comprising:
a display element layer comprising a pixel-defining layer defining a pixel opening, and a light-emitting element; and
an encapsulation layer above the display element layer, and comprising:
a first inorganic encapsulation layer having a refractive index of about 1.90 or more to about 2.10 or less above the display element layer;
a second inorganic encapsulation layer having a refractive index of about 1.90 or more to about 2.10 or less above the first inorganic encapsulation layer;
a third inorganic encapsulation layer having a refractive index of about 1.90 or more to about 2.10 or less above the second inorganic encapsulation layer; and
an organic encapsulation layer having a dielectric constant of about 1.0 or more to about 2.5 or less above the third inorganic encapsulation layer.

2. The display panel of claim 1, wherein the organic encapsulation layer is directly on the third inorganic encapsulation layer.

3. The display panel of claim 1, wherein the second inorganic encapsulation layer is directly on the first inorganic encapsulation layer, and
wherein the third inorganic encapsulation layer is directly on the second inorganic encapsulation layer.

4. The display panel of claim 1, wherein the first inorganic encapsulation layer, the second inorganic encapsulation layer, and the third inorganic encapsulation layer comprise a same material.

5. The display panel of claim 1, wherein the first inorganic encapsulation layer, the second inorganic encapsulation layer, and the third inorganic encapsulation layer comprise at least one of a silicon nitride, a silicon oxide, or a silicon oxynitride.

6. The display panel of claim 1, wherein the second inorganic encapsulation layer has a thickness that is greater than a thickness of the first inorganic encapsulation layer and is greater than a thickness of the third inorganic encapsulation layer.

7. The display panel of claim 1, wherein the first inorganic encapsulation layer and the third inorganic encapsulation layer have a thickness of about 1 Å or more to about 10 Å or less, and
wherein the second inorganic encapsulation layer has a thickness of about 1500 Å or more to about 2000 Å or less.

8. The display panel of claim 1, wherein the organic encapsulation layer has a thickness of about 3 μm or more to about 8 μm or less.

9. The display panel of claim 1, wherein a top surface of the second inorganic encapsulation layer comprises a planarized surface.

10. The display panel of claim 1, wherein the second inorganic encapsulation layer has a water vapor transmission rate of about 1×10−4 g/m²·day or more to about 9×10⁻⁴ g/m²·day or less.

11. The display panel of claim 1, wherein the encapsulation layer covers the light-emitting element.

12. The display panel of claim 1, wherein the light-emitting element comprises a first electrode exposed through the pixel opening, a second electrode above the first electrode, and a light-emitting layer between the first electrode and the second electrode.

13. The display panel of claim 12, wherein the light-emitting element further comprises a hole control layer between the first electrode and the light-emitting layer, and an electron control layer between the light-emitting layer and the second electrode.

14. The display panel of claim 1, wherein a top surface of the organic encapsulation layer defines an uppermost surface of the encapsulation layer.

15. A electronic device comprising:
an input sensor comprising conductive patterns,
a display panel below the input sensor, and comprising:
light-emitting areas;
a display element layer comprising a pixel-defining layer defining a pixel opening, and a light-emitting element; and
an encapsulation layer above the display element layer, and comprising:
a first inorganic encapsulation layer having a refractive index of about 1.90 or more to about 2.10 or less above the display element layer;
a second inorganic encapsulation layer having a refractive index of about 1.90 or more to about 2.10 or less above the first inorganic encapsulation layer;
a third inorganic encapsulation layer having a refractive index of about 1.90 or more to about 2.10 or less above the second inorganic encapsulation layer; and
an organic encapsulation layer having a dielectric constant of about 1.0 or more to about 2.5 or less above the third inorganic encapsulation layer.

16. The electronic device of claim 1, wherein the input sensor is directly on the organic encapsulation layer, and
the input sensor comprises:
a first sensor insulation layer directly on the organic encapsulation layer;
a first sensor conductive layer above the first sensor insulation layer;
a second sensor insulation layer above the first sensor insulation layer to cover the first sensor conductive layer; and
a second sensor conductive layer above the second sensor insulation layer.

17. The electronic device of claim 15, further comprising:
a housing accommodating the display panel and the input sensor.

18. A method for manufacturing a display panel comprising:
forming a display element layer comprising a pixel-defining layer and a light-emitting element; and
forming an encapsulation layer on the display element layer to cover the light-emitting element by:
forming a first inorganic encapsulation layer having a refractive index of about 1.90 or more to about 2.10 or less on the display element layer;
forming a second inorganic encapsulation layer having a refractive index of about 1.90 or more to about 2.10 or less on the first inorganic encapsulation layer;
forming a third inorganic encapsulation layer having a refractive index of about 1.90 or more to about 2.10 or less on the second inorganic encapsulation layer; and
forming an organic encapsulation layer having a dielectric constant of about 1.0 or more to about 2.5 or less on the third inorganic encapsulation layer.

19. The method of claim 18, wherein the forming of the first inorganic encapsulation layer comprises a plasma-enhanced atomic layer deposition (PEALD) or physical vapor deposition (PVD) process,
wherein the forming of the second inorganic encapsulation layer comprises a plasma-enhanced chemical vapor deposition (PECVD) process, and
wherein the forming of the third inorganic encapsulation layer comprises a PEALD or PVD process.

20. The method of claim 18, wherein the first inorganic encapsulation layer, the second inorganic encapsulation layer, and the third inorganic encapsulation layer are formed through a same silicon precursor.
